(19) United States
(12) Patent Application Publication
(10) Pub. No.: US 2015/0349019 A1
(43) Pub. Date: Dec. 3, 2015

(54) METHOD FOR MANUFACTURING SOLID-STATE IMAGE SENSING DEVICE

(71) Applicant: CANON KABUSHIKI KAISHA, Tokyo (JP)

(72) Inventors: Sho Suzuki, Yokohama-shi (JP); Kentaro Suzuki, Kawasaki-shi (JP); Takehito Okabe, Atsugi-shi (JP)

(21) Appl. No.: 14/727,516

(22) Filed: Jun. 1, 2015

(30) Foreign Application Priority Data
Jun. 3, 2014 (JP) 2014-115283

(51) Int. Cl. H01L 27/146

(52) U.S. Cl. CPC H01L 27/14685; H01L 27/14625; H01L 27/14636

(57) ABSTRACT

A method for manufacturing a solid-state image sensing device includes forming a first insulating film on a semiconductor substrate, planarizing the first insulating film, forming a second insulating film after the planarization, forming an opening in the first and the second insulating film, and forming an optical waveguide by forming a filling member in the opening. The thickness of the first insulating film is measured before the formation of the second insulating film, and the second insulating film is formed to a thickness according to the thickness of the first insulating film.

### BACKGROUND

1. Field

Aspects of the present application generally relate to a method for manufacturing a solid-state image sensing device.

2. Description of the Related Art

In order to increase the quantity of incoming light to the photoelectric conversion portion of a solid-state image sensing device, which is one of the semiconductor devices, a structure having an optical waveguide is devised.

Japanese Patent Laid-Open No. 2012-182427 discloses a method for manufacturing a solid-state image sensing device including an optical waveguide formed by filling an opening in an insulator with a high-refractive-index material. In this method, in order to facilitate the planarization of the filling member of the optical waveguide, the filling member is removed in part by etching before the planarization.

The present inventors have found that the height of the optical waveguide varies in some cases due to the manufacturing variations of the insulator even if the flatness of the filling member is improved by the method of the above-cited patent document. If the height of the optical waveguide varies, the properties of the optical waveguide vary. This may cause the luminance of the image to vary.

### SUMMARY

Accordingly, aspects of the present application provide a method for manufacturing a solid-state image sensing device in which the variation in height of an optical waveguide is reduced.

According to an aspect of the present disclosure, a method for manufacturing a solid-state image sensing device includes forming a first insulating film on a semiconductor substrate, planarizing the first insulating film, and forming a second insulating film after the planarization, forming an opening in the first and the second insulating film, and forming an optical waveguide by forming a filling member in the opening. The thickness of the first insulating film is measured after the planarization and before the formation of the second insulating film, and the second insulating film is formed to a thickness according to the thickness of the first insulating film.

Further features of the present disclosure will become apparent from the following description of exemplary embodiments with reference to the attached drawings.

### BRIEF DESCRIPTION OF THE DRAWINGS

FIGS. 1A to 1C are representations of a method for manufacturing a solid-state image sensing device according to a first embodiment.

FIGS. 2A to 2C are representations of the method for manufacturing the solid-state image sensing device according to the first embodiment.

FIGS. 3A and 3B are flow diagrams of the method for manufacturing the solid-state image sensing device according to the first embodiment.

FIG. 4 is a flow diagram of a method for manufacturing a solid-state image sensing device according to a second embodiment.

FIG. 5 is a flow diagram of a method for manufacturing a solid-state image sensing device according to a third embodiment.

FIG. 6 is a flow diagram of a method for manufacturing a solid-state image sensing device according to a fourth embodiment.

### DESCRIPTION OF THE EMBODIMENTS

The method for manufacturing a solid state image sensing device of the disclosure will now be described using exemplary embodiments in which a CMOS solid-state image sensing device is produced.

### First Embodiment

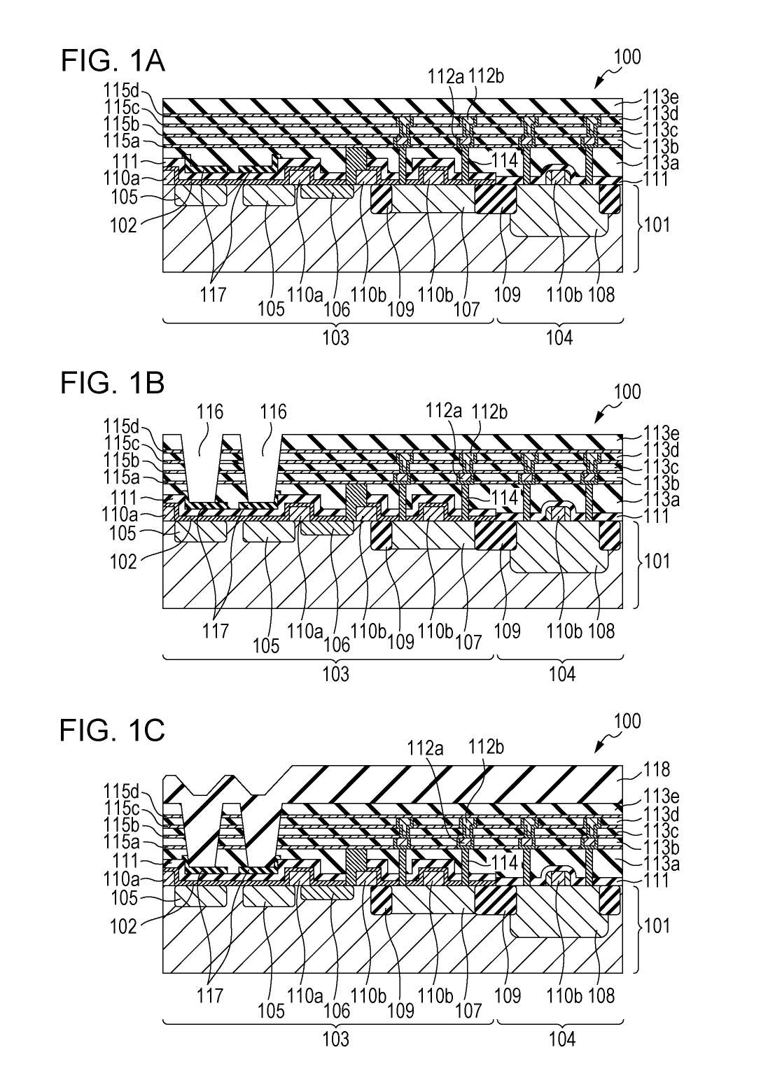

The solid-state image sensing device of a first embodiment will now be described with reference to FIGS. 1A to 3B. In the following description, parts that can be formed by conventional techniques will not be described in detail.

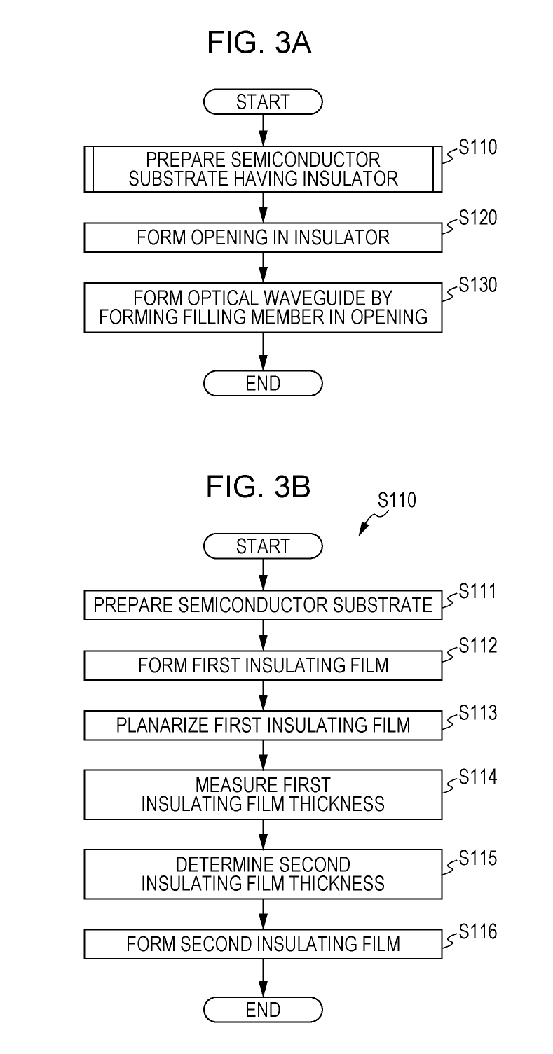

Referring now to FIGS. 3A and 3B, the process flow of the method will first be described. The method of the present embodiment includes Steps S110 to 5130, as shown in FIG. 3A. Step S110 is the step of preparing a semiconductor substrate including an insulator. Step S120 is the step of forming an opening in the insulator. Step S130 is the step of forming an optical waveguide by forming a filling member in the opening.

The height of the optical waveguide depends on the height (total thickness) of the insulator in Step S110. The optical waveguide is formed through the operation for forming an opening in the insulator (Step S120). For forming the opening, for example, the insulator is etched to be removed. In this operation, if the height of the upper surface of the insulator varies, the depth of the opening varies even if the insulator is removed to the same depth. Since the depth of the opening defines the height of the optical waveguide, the height of the insulator is important. It is desirable that the height of the insulator does not vary. The insulator includes a plurality of insulating film. The height of the insulator mentioned herein refers to the height from the upper surface of the semiconductor substrate, that is, the position of the upper surface of the insulator in relation to the upper surface of the semiconductor substrate.

In the formation of the insulator in the present embodiment, the following operation is performed before any of the steps of forming the second or higher order insulating film. This operation is the step of determining the thickness of the insulating film to be formed, according to the thickness of at least one insulating film that will underlie the insulating film to be formed, and forming the insulating film so that the upper surface thereof lies at a desired height. This operation will now be described in detail. Referring to FIG. 3B, Step S110 includes Steps S111 to S116. Step S111 is the step of preparing a semiconductor substrate. Step S112 is the step of forming a first insulating film. Step S113 is the step of planarizing the first insulating film. Step S114 is the step of measuring the thickness of the first insulating film. Step S115 is the step of determining the thickness of the second insulating film. Step S116 is the step of forming the second insulating film according to the result of Step S115. The term “desired height” mentioned herein may be a design value and has a tolerance.

In the present embodiment, after measuring the thickness of the first insulating film, the thickness of the second insulating film is determined, and then the second insulating film is formed on the first insulating film. Hence, the second insulating film is formed so as to have a height from the semiconductor substrate determined according to the thickness of the first insulating film. In the method of the present embodiment, the variation in height caused by planarization or the like is adjusted through the formation of the second insulating film. The variation in height of the optical waveguide thus can be reduced.

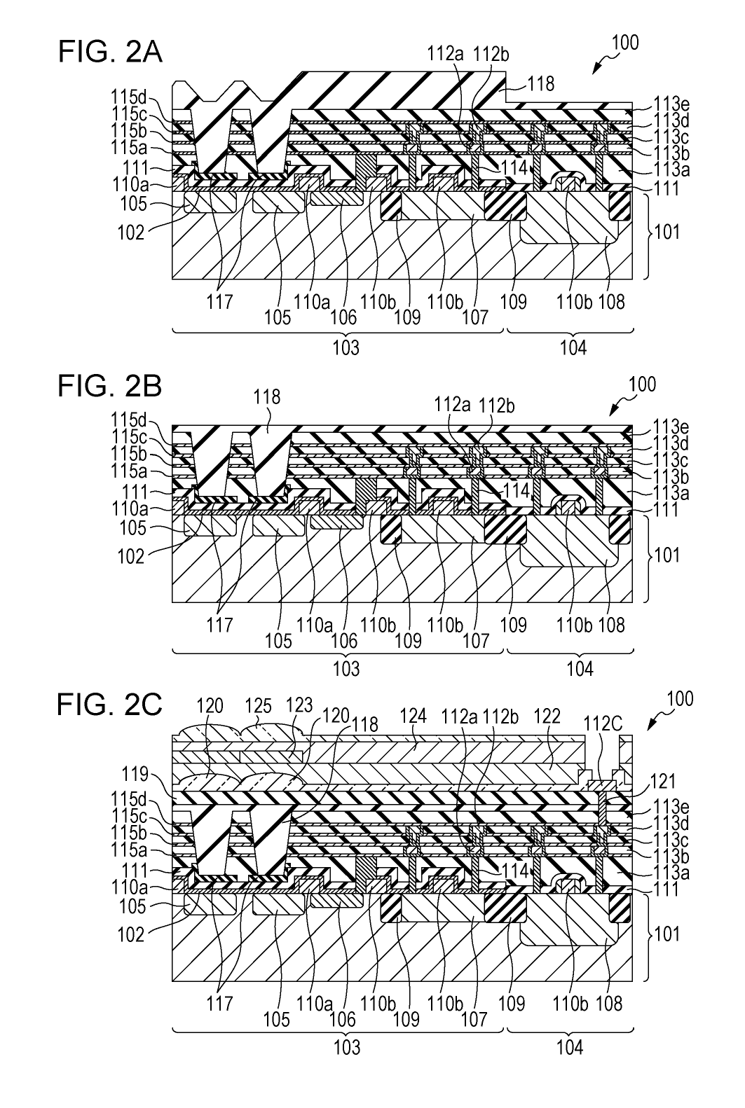

The method of the present embodiment will be further described with reference to FIGS. 1A to 2C. FIGS. 1A to 1C and 2A to 2C are sectional views of a solid-state image sensing device 100 in specific steps of the method of the present embodiment.

FIG. 1A shows Step S110 in FIGS. 3A and 3B of preparing a semiconductor substrate 101 provided with an insulator. The semiconductor substrate 101 is the semiconductor material portion of the solid-state image sensing device 100. For example, the semiconductor substrate 101 may be a semiconductor wafer in which semiconductor regions or the like have been formed by a known semiconductor process. The semiconductor material may be silicon. The upper surface 102 (main surface) of the semiconductor substrate 101 may define an interface with a thermally oxidized film in contact therewith. In the present embodiment, the semiconductor substrate 101 is an n-type semiconductor substrate including an n-type epitaxial layer. The semiconductor substrate 101 includes therein a plurality of semiconductor regions defining a plurality of elements. More specifically, the semiconductor substrate 101 includes an image sensing region 103 where a plurality of pixels are arranged, and a peripheral region 104 where a signal processing circuit adapted to process signals from the pixels is disposed.

In the image sensing region 103, photoelectric conversion elements 105, a floating diffusion portion (FD) 106, pixel transistors and a well 107 are disposed. The pixel transistors include an amplifying transistor and a reset transistor. The photoelectric conversion element 105 may be a photodiode that is an n-type semiconductor region functioning as a charge accumulation region. The FD 106 is an n-type semiconductor region. The FD 106, in the present embodiment, is electrically connected to the gate electrode 110b of the amplifying transistor via a plug 114. In another embodiment, however, the FD 106 may be electrically connected to a signal output line. The well 107 is provided with source and drain regions (not shown) of transistors such as the amplifying transistor adapted to amplify signals and a reset transistor adapted to reset the input node properties of the amplifying transistor. In the peripheral region 104, another well 108 is disposed which is provided with source and drain regions of peripheral transistors constituting the signal processing circuit. The semiconductor substrate 101 has element isolation portions 109. The element isolation portions 109 are insulators formed of silicon oxide by a shallow trench isolation (STI) process or the like.

The semiconductor substrate 101 is provided with gate electrodes 110a and 110b thereon. The gate electrodes 110a and 110b are each disposed on the upper surface 102 of the semiconductor substrate 101 with an insulating film such as a silicon oxide insulating film (not shown) therebetween. Gate electrode 110a controls the transfer of charges between the photoelectric conversion element 105 and the FD 106. Gate electrodes 110b are gates of the pixel transistors and peripheral transistors.

The insulator on the semiconductor substrate 101 includes a plurality of insulating films 113a to 113e. In the structure shown in FIG. 1A, the insulator includes a protective layer 111 formed on the upper surface 102 of the semiconductor substrate 101, etching stoppers 117, the plurality of insulating films 113a to 113e, and a plurality of anti-diffusion films 115a to 115d. The wiring structure includes, for example, a first wiring layer 112a, a second wiring layer 112b and plugs 114 electrically connecting the wiring layers. The insulating films 113a to 113e are intended to electrically isolate the wiring layers and the semiconductor substrate from each other. The protective layer 111 may a silicon nitride film or a multilayer film including a silicon nitride layer and a silicon oxide film. In the present embodiment, the protective layer 111 has a multilayer structure including a silicon nitride layer and a silicon oxide film in the image sensing region 103, and a silicon nitride single-layer structure in the peripheral region 104. The protective layer 111 may have the function of reducing damage that may be done by the photoelectric conversion elements in a subsequent step, and the function of preventing reflection, or the function of preventing the diffusion of metal in a silicidation step. Each etching stopper 117 is made of a silicon nitride film and desirably has an area larger than the area of the bottom of the corresponding opening 116 that will be formed later. The protective layer 111 and the etching stoppers 117 are not necessarily formed. The first wiring layer 112a and the second wiring layer 112b are formed of a conductive material mainly containing copper by a single damascene process or a dual damascene process. The plugs 114 are made of, for example, a conductive material mainly containing tungsten. The insulating films 113a to 113e may be formed of silicon oxide by plasma CVD (P-CVD) or high-density plasma CVD (HDP-CVD). Each anti-diffusion film 115 is disposed between each of the insulating films 113a to 113e, and may be made of silicon nitride. The anti-diffusion films 115a to 115d have the function of preventing the diffusion of the conductive material (metal) from the wiring layers, and may double as an etching stopper. The anti-diffusion films 115a to 115d are in contact with the upper surface of the wiring layers to exert the function thereof. For preventing the diffusion of copper, the anti-diffusion films may be formed of silicon nitride such as SiN or silicon carbide such as SiC.

The process for forming the insulator and the wiring structure will now be described. After an insulating film 113a is first formed on the semiconductor substrate, openings for the plugs 114 are formed in the insulating film 113a. For forming conductors in the openings, a conductive film is formed of a conductive material mainly containing tungsten in the openings and over the insulating film 113a. The tungsten formed on the insulating film 113a is removed by chemical mechanical polishing (CMP) or any other planarization technique, thus forming plugs 114. At this time, the insulating film 113a is also planarized by the planarization of the tungsten. The first wiring layer 112a is formed by a single damascene process. In this single damascene process, recesses of openings for the wiring layer are formed in insulating film 113b. Then, a conductive material film mainly containing copper is formed, followed by being planarized to yield the wiring layer 112a. The second wiring layer 112b is formed by a dual damascene process. In this dual damascene process, recesses or openings or the wiring layer is formed in insulating films 113c and 113d. Then, a conductive material film mainly containing copper is formed, followed by being planarized to yield the wiring layer 112b. In this process, insulating films 113b and 113d are planarized. In other words, insulating films 113b and 113d of the insulating films 113a to 113d are planarized.

Since at least one of the insulating films 113a to 113d is thus planarized when the insulator and the wiring structure are formed, the manufacturing variation caused by planarization can affect the height of the insulator. Even if the wiring layers of the wiring structure are formed of a material mainly containing aluminum, the insulating films covering the wiring layers can be planarized.

In order to keep constant the depth of the optical waveguide formed in a subsequent step, the thickness of the insulating films from insulating film 113a to insulating film 113d is measured, and the thickness of insulating film 113e is determined according to the difference from the ideal or intended thickness. Then, insulating film 113e is formed on insulating film 113d so as to have the determined thickness. Thus, in the present embodiment, insulating films 113a to 113d are formed as a first insulating film (Step S112), and at least insulating film 113d is planarized (Step S113). Then, the thickness from the insulating film 113a to insulating film 113d is measured (Step S114). According to the result of the measurement, the thickness of insulating film 113e is determined as the thickness of the second insulating film (Step S115), and insulating film 113e is formed (Step S116). The height of the optical waveguide is thus controlled through the method of the present embodiment.

The thickness from insulating film 113a to insulating film 113d may be measured by, for example, spectroscopic ellipsometry. The thickness may be measured by observing the section of a test sample of the semiconductor substrate through an SEM. Alternatively, if possible, the height may be measured from the upper surface 102 of the semiconductor substrate 101 to the upper surface of the insulating film.

The thickness of the second insulating film is determined as below according to the measured thickness value. If the measured thickness value is larger than the values in a predetermined design range, the thickness of the second insulating film is set to be smaller than the values in the predetermined design range; if the measured thickness value is smaller than the values in the predetermined design range, the thickness of the second insulating film is set to be larger than the values in the predetermined design range. For increasing or reducing the thickness of the second insulating film, the degree of the increase or reduction may be determined, for example, by adding or subtracting the error from the center value in the predetermined design range to or from the thickness of the second insulating film.

In the present embodiment, anti-diffusion film 115d is formed as a third insulating film between insulating films 113d and 113e. This anti-diffusion film 115d is formed by plasma CVD. The anti-diffusion film 115d is not subjected to planarization. Although the above-described thickness measurement may be performed after the formation of the anti-diffusion film 115d, it is not performed in the present embodiment. This is because the variation caused by forming the anti-diffusion film is smaller than the variation caused by planarization.

Then, openings are formed in the insulator as shown in FIG. 1B (Step S120). A plurality of openings 116 are formed in the insulator. A photoresist pattern is formed on insulating film 113e shown in FIG. 1A. The photoresist pattern has openings therein corresponding to the positions where the openings 116 are to be formed. Then, the insulator is dry-etched using the photoresist pattern as a mask to remove the portions of the insulator corresponding to the openings in the photoresist pattern, thus forming the openings 116 in the insulator. In the embodiment shown in FIG. 1B, the openings 116 expose the etching stoppers 117. The openings 116, however, may pass through the insulator or may remain in part at the bottom of the openings. The shape of the opening 116 in plan view is not limited to circle or quadrangle. Also, the opening 116 may spread across some of the photoelectric conversion elements 105. The openings 116 are formed right above the photoelectric conversion elements 105. Thus, in the present embodiment, a large number of openings 116 are formed in the image sensing region 103, while the peripheral region 104 does not have openings 116. In another embodiment, however, the opening 116 may be formed in the peripheral region 104.

Subsequently, optical waveguides are formed by forming filling members in the openings (Step S130). First, an optical waveguide member 118 is formed on the insulator having the openings, as shown in FIG. 1C. The optical waveguide member 118 is formed over the entirety of the image sensing region 103 and the peripheral region 104 so as to fill the openings 116. At this time, the optical waveguide member 118 is formed not only in the openings, but also on the insulator. The openings are not necessarily fully filled, and a void space may be formed in the filled portion.

A liner film (not shown) may be formed before forming the optical waveguide member 118. In other words, the step of forming the filling member may include the sub step of forming a first filling member that is a liner film, and the sub step of forming a second filling member that is the optical waveguide member 118. More specifically, the liner film (not shown) is formed on the side walls of the openings 116 and the third insulating film 113e. Then, the optical waveguide member 118 is formed to a larger thickness than the thickness of the liner film on the liner film. The liner film and the optical waveguide member 118 may be formed by deposition such as high-density plasma CVD, parallel plate plasma CVD or sputtering, or by applying an organic material such as polyimide-based polymer. The optical waveguide may be defined by a plurality of filling members. For example, after the formation of the liner film, the optical waveguide member 118 is formed, and then a further filling member may be formed of another material. For example, a silicon nitride liner film may be formed, and the optical waveguide member 118 may be formed of an organic material having high filling properties.

The material of the optical waveguide member 118 has a higher refractive index than the material of the insulating films 113a to 113e. If the insulating films 113a to 113e are made of silicon oxide, the optical waveguide member 118 may be made of silicon nitride or a polyimide-based organic material. A silicon nitride film has a refractive index in the range of 1.7 to 2.3. The surrounding silicon oxide film has a refractive index in the range of 1.4 to 1.6. Light incident on the interface between the optical waveguide member 118 and the insulating films 113a to 113e is reflected at the interface and thus confined in the optical waveguide member 118, according to Snell's law. Hence, the waveguide is defined by the filling member and the insulating films. The hydrogen content in the silicon nitride film can be increased, so that the effect of the silicon nitride film to supply hydrogen terminates the dangling bonds at the surface of the substrate. Thus, noise such as white flaws can be reduced. Polyimide-based organic materials have refractive indices of about 1.7. The filling property of the polyimide-based organic material is superior to that of the silicon nitride film. It is advantageous to select an appropriate material for the optical waveguide member 118 in view of the balance between the optical properties, such as refractive index, of the material and the advantages in manufacture. In spite of the above description, the refractive index of the optical waveguide member 118 is not necessarily higher than that of the insulating films 113a to 113e. The optical waveguide member 118 can function as the optical waveguide as long as the structure thereof does not allow incoming light to leak to the surrounding insulator. For example, a member capable of reflecting light may be formed as a first film on the side walls of the openings 116, and then the optical waveguide member 118 may be formed on the first film. An air gap may be formed between the optical waveguide member 118 in the opening 116 and the insulating films 113a to 113e. The air gap may be in vacuum or filled with a gas. In these cases, the refractive index of the material of the optical waveguide member 118 may have any relationship with the refractive index of the material of the insulating films 113a to 113e in terms of the magnitude of the values.

Furthermore, the step is performed of removing at least a part of the filling member overlying the insulator. At least a part of the portion of the optical waveguide member 118 overlying the insulator is removed, as shown in FIG. 2A. More specifically, the “part” refers to the portion of the optical waveguide member 118 disposed in the peripheral region 104. This removal may be performed by dry etching or a lift-off process, using a resist pattern (not shown) formed on the optical waveguide member 118 as a mask.

The part of the optical waveguide member 118 to be removed will now be described in terms of when viewed from above and when viewed in the depth direction. When viewed from above, the part is at least a part of the portion of the optical waveguide member 118 disposed in the peripheral region 104. Although at least a part may be removed, it is desirable to remove most of the portion overlying the insulator in the peripheral region 104. The entirety of the portion disposed in the peripheral region 104 may be removed. When viewed in the depth direction, the part is at least a part of the optical waveguide member 118 in the thickness direction thereof. In other words, the thickness of the portion of the optical waveguide member 118 disposed in the peripheral region 104 may be merely reduced so as to be smaller than the thickness thereof immediately after being formed. The phrase “at least a part” implies that although the entirety of the portion may be removed, it is desirable to leave the optical waveguide member 118 to the extent that the insulator is not exposed.

Turning to FIG. 2B, the step of planarizing the filling member will be described. The optical waveguide member 118 a part of which has been removed as shown in FIG. 2A is planarized by chemical mechanical polishing (CMP), mechanical polishing, etching, or the like. In the present embodiment, CMP is applied. The portion of the optical waveguide member 118 overlying the insulator desirably has a thickness in the range of 50 nm to 500 nm after being planarized. For example, the optical waveguide member 118 has a thickness in the range of 200 nm to 500 nm in the peripheral region 104, and a thickness in the range of 50 nm to 350 nm in the image sensing region 103 other than the region of the openings 116. The height of the waveguides from the bottom to the upper surface is desirably in the range of 1500 nm to 1900 nm. Hence, the design height (desired height) of the insulator is, for example, in the range of 1150 nm to 1850 nm. Since the depth of the openings 116 can be precisely controlled, it is easy to control the height of the waveguides in this range. The waveguides are thus formed.

Turning now to FIG. 2C, the rest of the process will be described. An insulating film 119, a third wiring layer 112c and a layer including in-layer lenses 120 are formed in that order on the upper surface of the planarized optical waveguide member 118, as shown in FIG. 2C. Then, a planarizing layer 122, a color filter layer 123, another planarizing layer 124 and a layer including microlenses 125 are formed in that order on the layer including the in-layer lenses 120.

Insulating film 119 may be formed of the same material as insulating film 113e, that is, silicon oxide. A plug 121 electrically connects the second wiring layer 112b to the third wiring layer 112c. The third wiring layer 112c is formed so as to be connected to the plug 121. In the present embodiment, the third wiring layer 112c is formed of a conductive material mainly containing aluminum. The in-layer lenses 120 and the microlenses 125 are arranged corresponding to the photoelectric conversion elements 105. The layer including the in-layer lenses 120 may be formed of silicon nitride. The layer including the in-layer lenses 120 may be provided with antireflection films made of, for example, silicon nitride thereon and thereunder. The planarizing layer 122, the color filter layer 123, the planarizing layer 124 and the layer including microlenses 125 each may be formed of an organic material. The layer including the microlenses 125 may be provided with an antireflection film made of, for example, silicon oxide thereon. Thus, the solid-state image sensing device is completed.

The method of the present embodiment enables the height of the optical waveguide from the bottom to the upper surface to be controlled in a predetermined range, consequently reducing the variation in optical properties of the solid-state image sensing device.

### Modification of First Embodiment

The step of removing the optical waveguide member 118 from the peripheral region 104 may be performed after the step shown in FIG. 2B. In this step, it is advantageous to remove the portion of the optical waveguide member 118 disposed within a certain distance from the position where the plug 121 will be formed. The removal is performed before forming the insulating film 119. This step makes it easy to form a through hole for the plug 121.

### Second Embodiment

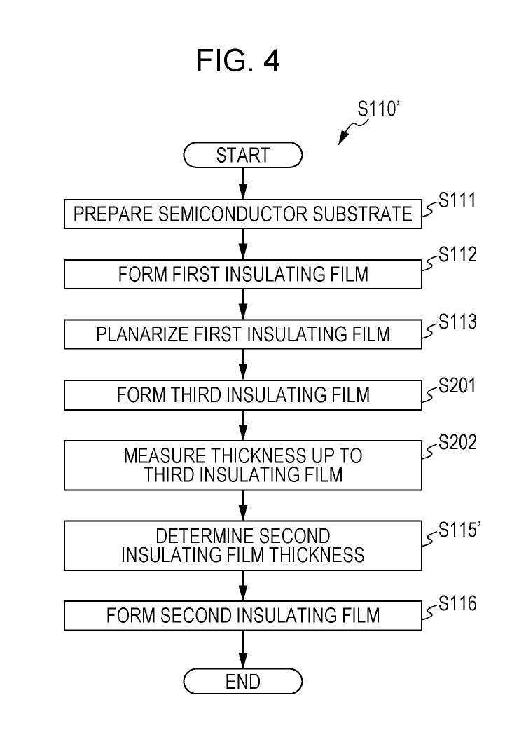

A second embodiment will now be described with reference to FIG. 4. FIG. 4 is a flow diagram illustrating the method of the present embodiment, corresponding to FIG. 3B. The same steps as in FIG. 3B are designated by the same reference numerals, and thus description thereof is omitted. Step S110′ in the present embodiment forms the third insulating film (Step S201) and measures the thickness from the semiconductor substrate to the third insulating film (Step S202), between Steps S113 and S116. Then, the thickness of the second insulating film is determined according to the measured thickness from the semiconductor substrate to the third insulating film (Step S115′).

Unlike the operation shown in FIG. 1A of the first embodiment, thickness measurement is performed to determine the thickness of the second insulating film after the third insulating film or the anti-diffusion film 115d has been formed. Since the thickness of the second insulating film can be adjusted even in this process, the height of the optical waveguide can be controlled through the method of the present embodiment.

### Third Embodiment

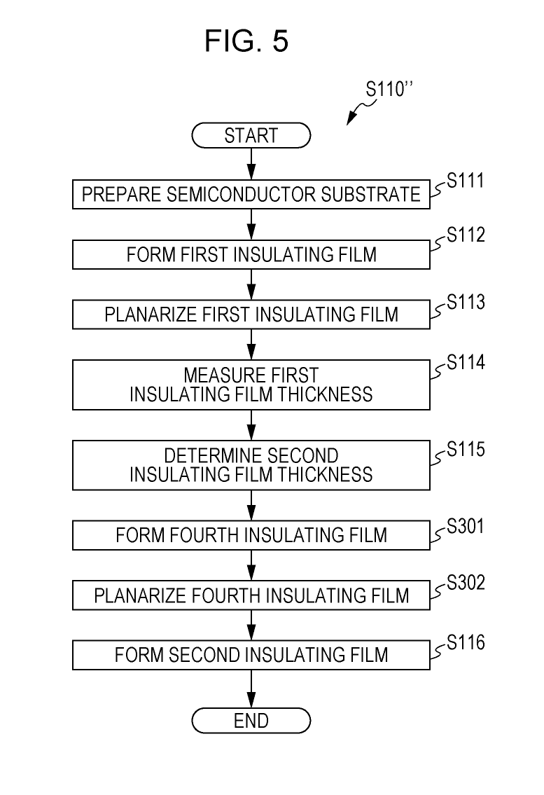

A third embodiment will now be described with reference to FIG. 5. FIG. 5 is a flow diagram illustrating the method of the present embodiment, corresponding to FIG. 3B. The same steps as in FIG. 3B are designated by the same reference numerals, and thus description thereof is omitted. Step S110″ in the present embodiment forms a fourth insulating film (Step S301) and planarizes the fourth insulating film (Step S302), between Steps S115 and S116. In this process, the thickness of the second insulating film is determined allowing for the variation in thickness of at least one layer. Thus, the variation in height of the optical waveguide can be reduced.

### Fourth Embodiment

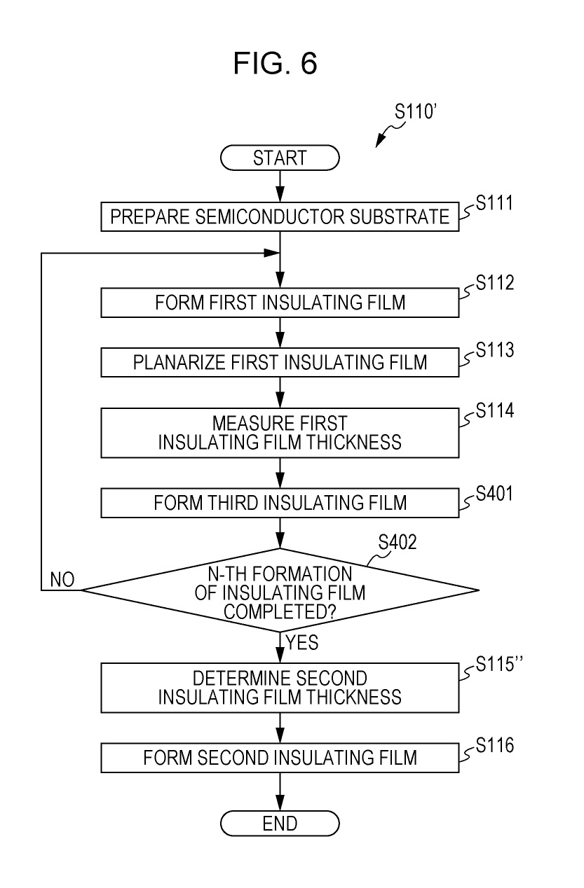

A fourth embodiment will now be described with reference to FIG. 6. FIG. 6 is a flow diagram illustrating the method of the present embodiment, corresponding to FIG. 3B. The same steps as in FIG. 3B are designated by the same reference numerals, and thus description thereof is omitted. Step S110″′ in the present embodiment forms the third insulating film (Step S401) and determines whether or not the N-th insulating film formation is completed (Step S402), between Steps S114 and S115″. Hence, the formation of the first insulating film and the third insulating film from Step S112 to Step S401 is repeated a plurality of times. N is an arbitrary number. The thickness of each of the first insulating films is measured (Step S114) every time after the formation, and then the thickness of the second insulating film is determined (Step S115″).

If the measurement of the thickness is performed by spectroscopic ellipsometry, it is easier and more accurate to measure a single insulating film than to measure a set of a plurality of insulating films. Therefore, by measuring the thickness of each of a plurality of planarized insulating films as in the present embodiment, more precise optical waveguides can be easily formed.

### Fifth Embodiment

The fifth embodiment will illustrate the case of manufacturing image sensing devices on a plurality of wafers using any one of the methods of the first to fourth embodiments. In the following description, the term “a/the plurality of wafers” refers to wafers to be worked at one time in the same lot.

In the present embodiment, at least one wafer (first wafer) of a plurality of wafers is subjected to the step of measuring the first insulating film and the step of determining the second insulating film. For the other wafers, the second insulating film is formed to a thickness according to the result of the thickness measurement of the first wafer, without measuring the thickness of the first insulating film.

This method can reduce the number of times of thickness measurement and accordingly increase productivity. Although the plurality of wafers mentioned in the present embodiment refer to wafers to be worked at one time in the same lot, the wafers may be in an arbitrary unit without being limited to the same lot.

The method of the application for manufacturing a solid-state image sensing device is not limited to the disclosed embodiments, and various modifications or combinations may be appropriately made.

In the method of the present embodiment, the variation in height caused by planarization or the like is adjusted through the formation of the second insulating film. The variation in height of the optical waveguide thus can be reduced.

While the present disclosure has been described with reference to exemplary embodiments, it is to be understood that these exemplary embodiments are not seen to be limiting.

This application claims the benefit of Japanese Patent Application No. 2014-115283, filed Jun. 3, 2014, which is hereby incorporated by reference herein in its entirety.

What is claimed is:

1. A method for manufacturing a solid-state image sensing device, the method comprising:
forming a first insulating film on a semiconductor substrate;
planarizing the first insulating film;
forming a second insulating film after the planarizing;
forming an opening in the first insulating film and the second insulating film; and
forming an optical waveguide by forming a filling member in the opening,
wherein a thickness of the first insulating film is measured after the planarizing and before the forming of the second insulating film, and the second insulating film is formed to a thickness according to the thickness of the first insulating film.

2. The method according to claim 1, wherein the thickness of the second insulating film is determined according to the measured thickness of the first insulating film before the forming of the second insulating film.

3. The method according to claim 1, wherein the planarizing of the first insulating film is performed by a chemical mechanical polishing method.

4. The method according to claim 1, wherein the first insulating film and the second insulating film are formed of silicon oxide.

5. The method according to claim 1, further comprising forming a third insulating film between the measuring of the thickness and the forming of the second insulating film, wherein the third insulating film is not planarized before the forming of the second insulating film.

6. The method according to claim 5, wherein the third insulating film is formed of one of silicon nitride and silicon carbide.

7. The method according to claim 5, further comprising forming a wiring layer before the forming of the third insulating film, wherein the third insulating film is formed so as to come in contact with an upper surface of the wiring layer.

8. The method according to claim 1, wherein the forming of the optical waveguide is performed so that the optical waveguide has a height in the range of 1500 nm to 1900 nm from a bottom thereof to an upper surface thereof.

9. The method according to claim 1, wherein the filling member is formed of silicon nitride.

10. A method for manufacturing a solid state image sensing device, the method comprising:
forming a first silicon oxide film on a semiconductor substrate;
forming a first wiring layer on the first silicon oxide film;
forming a first anti-diffusion film on the first wiring layer;
forming a second silicon oxide film after the forming of the first anti-diffusion film;
forming a second wiring layer on the second silicon oxide film;
forming a second anti-diffusion film on the second wiring layer;
forming a third silicon oxide film after the forming of the second anti-diffusion film;
forming an opening in the first silicon oxide film, the first anti-diffusion film, the second silicon oxide film, the second anti-diffusion film and the third silicon oxide film; and
forming an optical waveguide by forming a filling member in the opening,
wherein a thickness of the first silicon oxide film is measured after the forming of the first wiring layer and before the forming of the first anti-diffusion film, and a thickness of the second silicon oxide film is measured after the forming of the second wiring layer and before the forming of the second anti-diffusion film, and
wherein a thickness of the third silicon oxide film is determined according to the thicknesses of the first silicon oxide film and the second silicon oxide film, and the third silicon oxide film is formed to the determined thickness.

11. The method according to claim 10, wherein the first wiring layer is formed by a single damascene process, and the second wiring layer is formed by a dual damascene process.

12. The method according to claim 7, wherein the wiring layer mainly contains copper.

13. The method according to claim 10, wherein the first wiring layer and second wiring layer mainly contain copper.
